(19) United States
(12) Patent Application Publication
(10) Pub. No.: US 2026/0206627 A1
(43) Pub. Date: Jul. 16, 2026

(54) SEMICONDUCTOR STRUCTURE INCLUDING DUAL-SIDE HIGH-DENSITY SUBSTRATE AND MANUFACTURING METHOD THEREOF

(71) Applicant: Dyi-Chung HU, Hsinchu County (TW)

(72) Inventor: Dyi-Chung HU, Hsinchu County (TW)

(21) Appl. No.: 19/026,253

(22) Filed: Jan. 16, 2025

(51) Int. Cl. H01L 23/498; H01L 21/48

(52) U.S. Cl. CPC H10W 70/69; H10W 70/095; H10W 70/097; H10W 70/635

(57) ABSTRACT

A semiconductor structure includes a substrate which includes a core layer, a through core via penetrating through the core layer, a first redistribution structure disposed on a side of the core layer, and a second redistribution structure disposed on an opposing side of the core layer and electrically coupled to the first redistribution structure through the through core via. The first redistribution structure includes an outermost dielectric layer, an outermost conductive pattern disposed in and on the outermost dielectric layer and electrically coupled to the through core via, an inner dielectric layer between the outermost dielectric layer and the core layer. An outermost surface of the outermost dielectric layer includes a portion rougher than a surface of the inner dielectric layer facing the outermost dielectric layer.

### BACKGROUND

### Technical Field

The present invention relates to a semiconductor structure and a manufacturing method thereof, and more specifically relates to a semiconductor structure including a dual-side and high-density substrate and a manufacturing method thereof.

### Description of Related Art

For substrates used in high performance computing applications, a high-density substrate is needed. However, conventional dual-side substrates are limited to achieve fine lines due to the limitation of double-sided processes and associated equipment, since the current equipment can merely make the redistribution layer having fine lines on one side instead of dual sides. For this reason, a need exists to provide a dual-side and high-density substrate for a high performance computing device.

### SUMMARY

The disclosure provides a semiconductor structure having a dual-side and high-density substrate and a manufacturing method thereof, which has better reliability and yield.

A semiconductor structure includes a substrate which includes a core layer, a through core via penetrating through the core layer, a first redistribution structure disposed on a side of the core layer, and a second redistribution structure disposed on an opposing side of the core layer and electrically coupled to the first redistribution structure through the through core via. The first redistribution structure includes an outermost dielectric layer, an outermost conductive pattern disposed in and on the outermost dielectric layer and electrically coupled to the through core via, an inner dielectric layer between the outermost dielectric layer and the core layer. An outermost surface of the outermost dielectric layer includes a portion rougher than a surface of the inner dielectric layer facing the outermost dielectric layer.

A manufacturing method of a semiconductor structure includes: forming a through core via in a core layer, where the core layer includes a first side and a second side opposite to the first side, and the through core via extends between the first and second sides; forming a first redistribution structure on the first side of the core layer; bonding a temporary protection structure to the first redistribution structure, where the temporary protection structure includes a temporary carrier and a temporary adhesive layer bonding the temporary carrier to an outermost surface of the first redistribution structure, and a surface planarity of a surface the temporary adhesive layer connected to the temporary carrier is better than a surface planarity of the outermost surface of the first redistribution structure; forming a second redistribution structure on the second side of the core layer using the temporary protection structure as a support; and de-bonding the temporary protection structure from the first redistribution structure.

Based on the above, the use of the temporary protection structure during the formation of the substrate may facilitate compensation of the warpage of the work-in process (e.g., the first redistribution structure and the core layer) and reduction of the surface non-planarity of the work-in process. In this manner, the overall flatness of the substrate may be improved, and the reliability and yield of the semiconductor structure may also be improved.

To make the above features and advantages of the present invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1-11 are schematic cross-sectional views illustrating a manufacturing method of a semiconductor structure having a dual-side and high-density substrate according to some embodiments.

FIG. 12 is a schematic cross-sectional view illustrating a dual-side and high-density substrate according to some embodiments.

FIG. 13 is a schematic cross-sectional view illustrating a dual-side and high-density substrate according to some embodiments.

FIG. 14 is a schematic cross-sectional view illustrating a semiconductor structure having a dual-side and high-density substrate according to some embodiments.

FIG. 15 is a schematic cross-sectional view illustrating a dual-side and high-density substrate according to some embodiments.

FIG. 16 is a schematic cross-sectional view illustrating a semiconductor structure having a dual-side and high-density substrate according to some embodiments.

### DESCRIPTION OF THE EMBODIMENTS

Exemplary embodiments of the disclosure are described below comprehensively with reference to the figures, but the disclosure may also be implemented in different ways and should not be construed as limited to the embodiments described herein. In the drawings, for the sake of clarity, the size and thickness of various regions, parts, and layers may not be drawn to actual scale. In order to facilitate understanding, the same elements in the following description are described with the same symbols.

The disclosure is more comprehensively described with reference to the figures of this embodiment. However, the disclosure may also be implemented in various different forms, and is not limited to the embodiments in the present specification. Thicknesses, dimensions, and sizes of layers or regions in the drawings are exaggerated for clarity. The same reference numbers are used in the drawings and the description to indicate the same or like parts, which are not repeated in the following embodiments. Directional terms (for example, upper, lower, right, left, front, back, top, and bottom) used herein only refer to the graphical use, and are not intended to imply absolute orientation.

It should be understood that, although the terms “first”, “second”, “third”, or the like may be used herein to describe various elements, components, regions, layers, and/or portions, these elements, components, regions, and/or portions should not be limited by these terms. These terms are only used to distinguish one element, component, region, layer, or portion from another element, component, region, layer, or portion. Unless otherwise defined, all terms (including technical and scientific terms) used herein have the same meaning as that commonly understood by one of ordinary skill in the art to which this disclosure belongs.

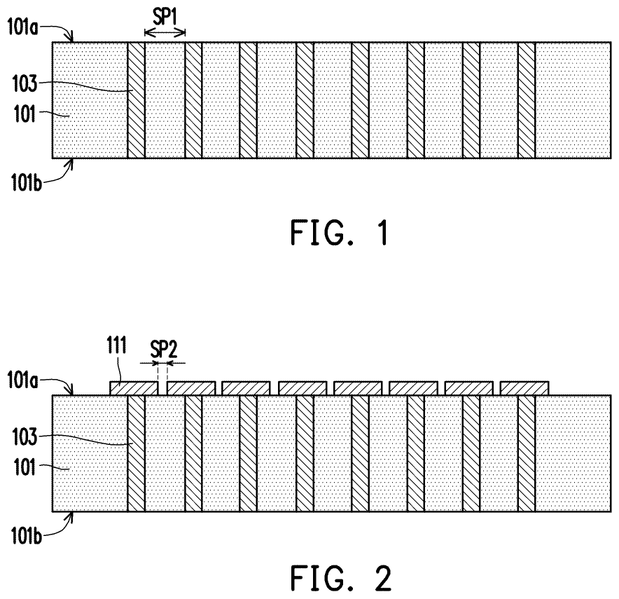

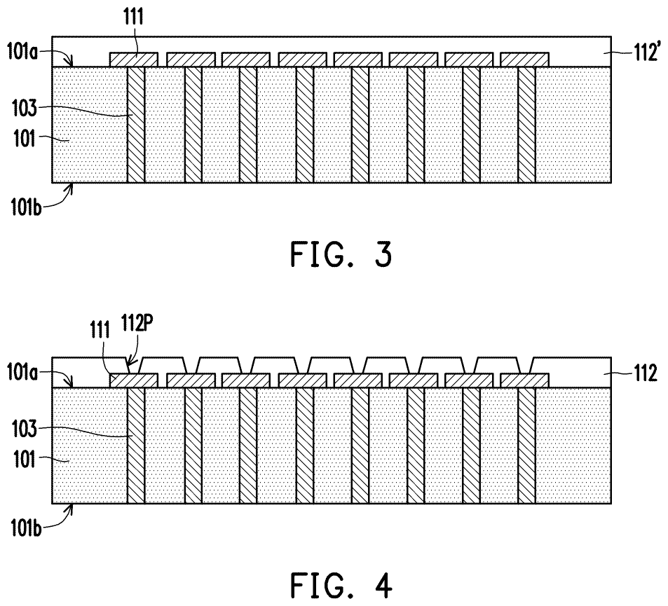

FIGS. 1-11 are schematic cross-sectional views illustrating a manufacturing method of a semiconductor structure having a dual-side and high-density substrate according to some embodiments. Referring to FIG. 1, a core layer 101 with through core vias 103 is provided. For example, the core layer 101 includes a first side 101a and a second side 101b opposite to the first side 101a, and the respective through core via 103 extends between the first side 101a and the second side 101b. In some embodiments, the core layer 101 is made of one or more inorganic material(s) (e.g., glass, ceramic, a combination thereof, etc.), one or more thermal stable material(s), and/or the like. In embodiments where the core layer 101 is made of glass, the through core vias 101 are referred to as through glass vias (TGVs). The respective through core via 103 may include one or more conductive material(s) such as copper, gold, nickel, aluminium, platinum, tin, combinations thereof, alloys thereof, etc. For example, a spacing SP1 of two adjacent through core vias 103 is on the order of few microns to facilitate the high-density layout.

Referring to FIG. 2 and FIG. 1, first conductive pads 111 are formed on the first side 101a of the core layer 101 and connected to the through core vias 103. The respective first conductive pad 111 may include one or more conductive material(s) such as copper, gold, nickel, aluminium, platinum, tin, combinations thereof, alloys thereof, etc. In some embodiments, the first conductive pads 111 and the through core vias 103 have a one-to-one correspondence. However, the first conductive pads 111 and the through core vias 103 may have a different configuration than shown. For example, a spacing SP2 of two adjacent first conductive pads 111 is less than the spacing SP1 (labelled in FIG. 1). In some embodiments, the spacing SP2 is on the order of a few microns to facilitate the high-density layout.

Referring to FIGS. 3-4 and FIG. 2, a first dielectric material layer 112′ is formed on the first side 101a of the core layer 101 and may embed the first conductive pads 111 therein. For example, the first dielectric material layer 112′ is made of one or more organic polymer(s), one or more photosensitive material, or any suitable dielectric material(s) which can be used for forming the fine circuity/lines. In some embodiments, the first dielectric material layer 112′ is made of a photosensitive polyimide. Next, portions of the first dielectric material layer 112′ are removed to form a first dielectric layer 112 with openings 112P through, e.g., lithography and etching, or any suitable patterning process. For example, at least a portion of the first conductive pads 111 is exposed by the openings 112P for further electrical connection. In some embodiments, a portion of the respective first conductive pad 111 is exposed by one of the openings 112P. However, the openings 112P and the corresponding first conductive pads 111 may have a different configuration than shown.

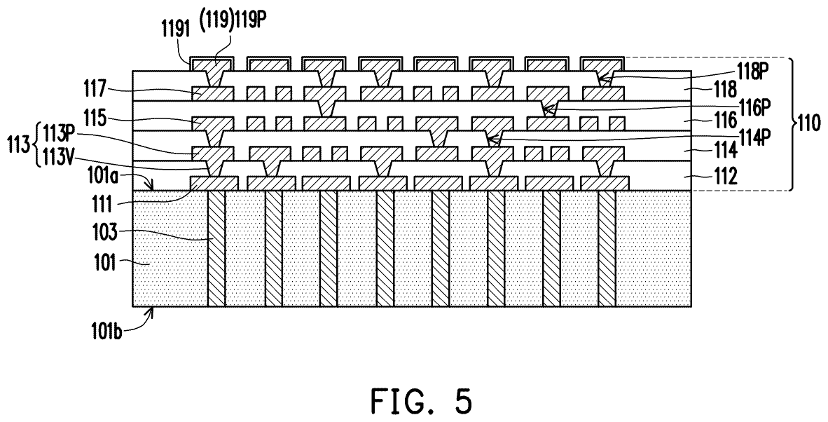

Referring to FIG. 5 and FIG. 4, a first conductive pattern 113 is formed in and on the first dielectric layer 112. The first conductive pattern 113 may include one or more conductive material(s) same as or similar to the material(s) of the first conductive pads 111. For example, the first conductive pattern 113 includes via portions 113V formed in the openings 112P of the first dielectric layer 112 to be in physical and electrical contact with the corresponding first conductive pads 111. The respective via portion 113V may be tapered in a direction from the first side 101a toward the second side 101b. The first conductive pattern 113 may further include pad portions 113P connected to the via portions 113V and overlying the first dielectric layer 112. The first conductive pattern 113 may further include line portions (not shown) connected to the pad portions 113P and horizontally extending on the first dielectric layer 112. After forming the first conductive pattern 113, a second dielectric layer 114 including openings 114P may be formed on the first dielectric layer 112 to cover the first conductive pattern 113. For example, at least a portion of the first conductive pattern 113 is exposed by the openings 114P of the second dielectric layer 114. The material of the second dielectric layer 114 may be the same as (or similar to) the material of the underlying first dielectric layer 112. Alternatively, the materials of the first and second dielectric layers are different.

With continued reference to FIG. 5, a second conductive pattern 115 may be formed on the second dielectric layer 114 and fill the openings 114P of the second dielectric layer 114 to be in physical and electrical contact with the first conductive pattern 113. The material and formation of the second conductive pattern 115 may be similar to those of the first conductive pattern 113. Next, a third dielectric layer 116 having openings 116P may be formed on the second dielectric layer 114 to cover the second conductive pattern 115. The material and the formation of the third dielectric layer 116 may be similar to those of the first dielectric layer 112. In some embodiments, a third conductive pattern 117 may be formed on the third dielectric layer 116 and fill the openings 116P of the third dielectric layer 116 to be in physical and electrical contact with the second conductive pattern 115, and then an outermost dielectric layer 118 having openings 118P may be formed on the third dielectric layer 116 to cover the third conductive pattern 117. The forming processes and materials of the third conductive pattern 117 and the outermost dielectric layer 118 may be similar to those of the first conductive pattern 113 and the first dielectric layer 112, respectively.

Still referring to FIG. 5, an outermost conductive pattern 119 may be formed on the outermost dielectric layer 118 and fill the openings 118P of the outermost dielectric layer 118 to be in physical and electrical contact with the third conductive pattern 117. In some embodiments, a surface finishing process is performed on the pad portions 119P of the outermost conductive pattern 119. For example, a surface finishing layer 1191 is conformally deposited on the outer surface (e.g., including the top surface and the sidewalls connected to the corresponding top surface) of the respective pad portion 119P of the outermost conductive pattern 119. The surface finishing layer 1191 may include one or more conductive material(s) such as copper, nickel, gold, the like, etc. Alternatively, the surface finishing process is skipped and the surface finishing layer 1191 is omitted. The combination of the dielectric layers (e.g., 112, 114, 116, and 118), the conductive patterns (e.g., 113, 115, 117, and 119), and the first conductive pads 111 may be collectively viewed as a first redistribution structure 110. It is understood that the configuration of the first redistribution structure 110 shown herein is only for illustrative purpose, and the number of the dielectric layers and the number of the conductive patterns can be selected based on product and circuit requirements and are not limited in the disclosure.

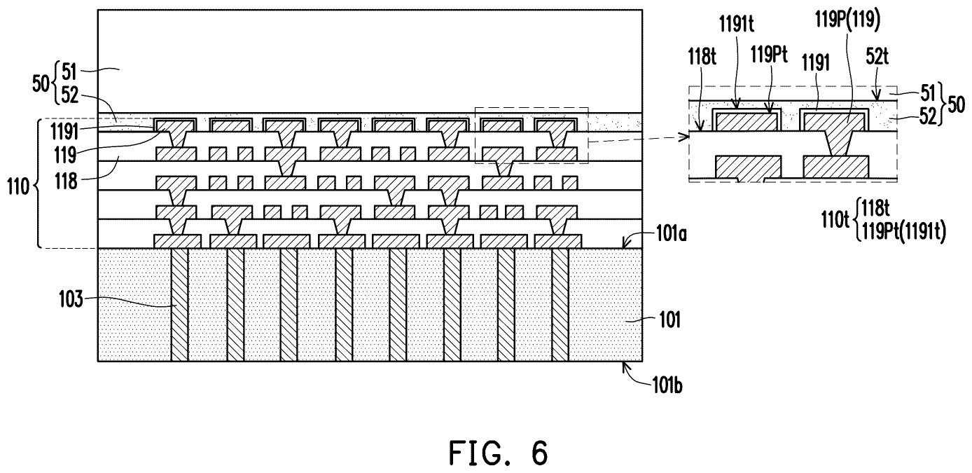

Referring to FIG. 6 and FIG. 5, a temporary protection structure 50 is provided and bonded to the first redistribution structure 110. In some embodiments, the temporary protection structure 50 includes a temporary carrier 51 provided with a temporary adhesive layer 52. For example, the temporary carrier 51 is adhered to the outermost dielectric layer 118 and the outermost conductive pattern 119 through the temporary adhesive layer 52. The pad portions 119P of the outermost conductive pattern 119 may be embedded in the temporary adhesive layer 52. The temporary adhesive layer 52 may include any suitable material(s) that can be removed by applying the external energy (e.g., UV light, visible light, heat, etc.) to the temporary adhesive layer 52. In the subsequently-performed de-bonding process, by removing the temporary adhesive layer 52, the temporary carrier 51 may be de-bonded from the first redistribution structure 110.

In some embodiments where the temporary adhesive layer 52 is thick enough, the pad portions 119P of the outermost conductive pattern 119 (or the surface finishing layer 1191 covering the pad portions 119P, if any) is separated from the temporary carrier 51 through the temporary adhesive layer 52. As shown in the enlarged view in FIG. 6, the pad portions 119P of the outermost conductive pattern 119 are protruded from the outermost surface 118t of the outermost dielectric layer 118t. The outermost surface 118t of the outermost dielectric layer 118 and the outermost surfaces 119Pt of the pad portions 119P (or the outermost surfaces 1191t of the surface finishing layer 1191, if any) may be collectively viewed as an outermost surface 110t of the first redistribution structure 110, and the outermost surface 110t is uneven. The temporary adhesive layer 52 may fully cover the unevenness of the outermost surface 110t of the first redistribution structure 110. For example, as shown in the enlarged view, the top surface 52t of the temporary adhesive layer 52 connected to the temporary carrier 51 is higher than the outermost surfaces 119Pt of the pad portions 119P (or the outermost surface 1191t of the surface finishing layer 1191, if any). The top surface 52t of the temporary adhesive layer 52 may be flatter than the outermost surface 110t of the first redistribution structure 110.

With continued reference to FIG. 6, the temporary carrier 51 of the temporary protection structure 50 may be provided in a sheet form, a film form, or the like. In some embodiments where the temporary carrier 51 is a temporary sheet, the temporary carrier 51 provided with the temporary adhesive layer 52 may absorb the surface non-planarity of the first redistribution structure 110, where the surface non-planarity (or the uneven surface) of the first redistribution structure 110 is caused by the profiles (or morphology) of the pad portions 119P and the outermost dielectric layer 118. In embodiments where the temporary carrier 51 provided in the sheet form, the temporary carrier 51 is made of one or more inorganic material(s) such as glass, metal, ceramic, a combination thereof, etc. In some embodiments where the temporary carrier 51 is a temporary sheet, the temporary carrier 51 resists the process chemicals of the subsequently-performed processes (e.g., forming a second redistribution structure). The temporary carrier 51 provided in the sheet form may have a Young's modulus higher than a Young's modulus of any one of the dielectric layers (e.g., 112, 114, 116, and 118) of the first redistribution structure 110. The coefficient of thermal expansion (CTE) of the temporary carrier 51 provided in a sheet form may be greater than the CTE of the core layer 101 (e.g., made of glass). Since the temporary carrier 51 has a higher CTE, the warpage of the first redistribution structure 110 formed at the first side 101a of the core layer 101 may be compensated. By selecting suitable CTE for the temporary carrier 51, the warped structure of the first redistribution structure 110 and the core layer 101 may be flatten, and the overall warpage of the structure may be reduced.

Still referring to FIG. 6, in some embodiments where the temporary carrier 51 is a temporary film, the temporary carrier 51 may have the high chemical resistance so that the process chemicals of the subsequently-performed processes (e.g., forming a second redistribution structure) do not substantially affect the temporary protection structure 50. In embodiments where the temporary carrier 51 is the temporary film, the temporary adhesive layer 52 of the temporary protection structure 50 may absorb the surface non-planarity of the first redistribution structure 110 which is caused by the profiles of the pad portions 119P and the outermost dielectric layer 118. No matter what type (e.g., sheet, film, or the like) is adopted for the temporary carrier 51, the temporary protection structure 50 may serve as a warpage-control structure. By bonding the temporary protection structure 50 to the first redistribution structure 110, the planarity (e.g., flatness) of the overall structure may be controlled and/or improved.

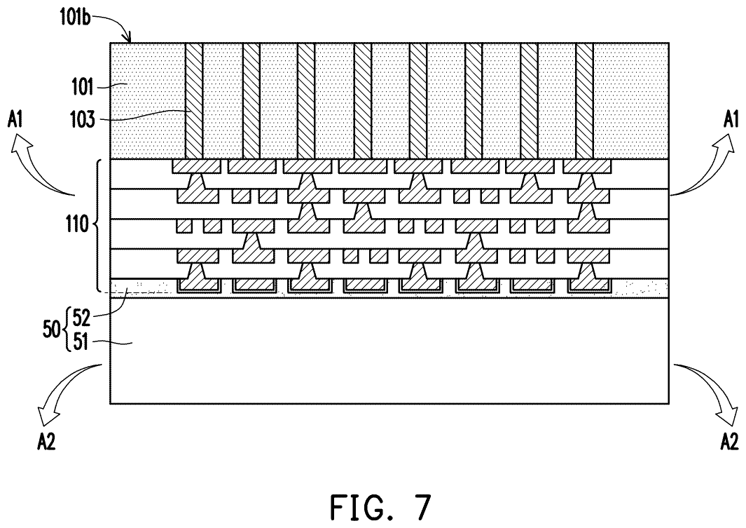

Referring to FIG. 7 and FIG. 6, the structure shown in FIG. 6 may be flipped upside-down, and the subsequent processes may be performed on the second side 101b of the core layer 101. For example, the CTE mismatch between the core layer 101 and the first redistribution structure 110 may result in warpage. As mentioned in the preceding paragraphs, the temporary protection structure 50 may serve as a warpage-control structure, and by selecting suitable CTE for the temporary carrier 51 of the temporary protection structure 50, the warped structure of the core layer 101 and the first redistribution structure 110 may be flattened, and the overall warpage of the structure may be reduced. In some embodiments, the structure of the core layer 101 and the first redistribution structure 110 has a concave warpage (warped part with a smiling-shape cross-section), as shown indicated by the arrow A1. In a case of having the concave warpage, the central portion of the structure is lower than the peripheral portion of the structure, relative to the temporary protection structure 50. The material of the temporary carrier 51 may be selected to have the lower CTE than the CTE of the dielectric layers of the first redistribution structure 110. For example, the temporary protection structure 50 may have a convex warpage (warped part with a crying-shape cross-section), as shown indicated by the arrow A2. By bonding the temporary protection structure 50 having the convex warpage to the structure having the concave warpage, the overall warpage of the bonded structure may be reduced.

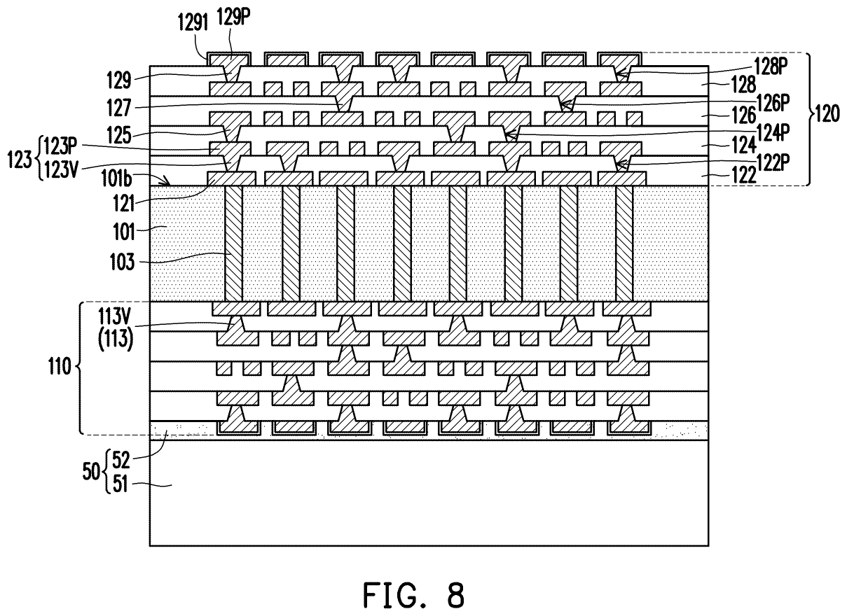

Referring to FIG. 8 and FIG. 7, a second redistribution structure 120 is formed on the second side 101b of the core layer 101 and connected to the through core vias 103, where the temporary protection structure 50 may serve as a support during the formation of the second redistribution structure 120. The materials and formation of the second redistribution structure 120 may be similar to those of the first redistribution structure 110. For example, a second conductive pads 121 is formed on the second side 101b of the core layer 101 and connected to the through core vias 103. In some embodiments, the second conductive pads 121 and the through core vias 103 have a one-to-one correspondence. For example, a spacing of two adjacent second conductive pads 121 is less than the spacing SP1 (labelled in FIG. 1) of the through core vias 103 and may be on the order of a few microns to facilitate the high-density layout. In some embodiments, the spacing of two adjacent second conductive pads 121 is substantially equal to the spacing SP2 (labelled in FIG. 2) of the first conductive pads 111. In alternative embodiments, the second conductive pads 121 may have a greater line/spacing (L/S) than the first conductive pads 111.

Next, a first dielectric layer 122 with openings 122P may be formed on the second side 101b of the core layer 101 and partially cover the second conductive pads 121. For example, at least a portion of the respective second conductive pad 121 is exposed by the openings 122P for further electrical connection. The material of the first dielectric layer 122 may be the same as or similar to that of the first dielectric layer 112. A first conductive pattern 123 may then be formed in and on the first dielectric layer 122. For example, the first conductive pattern 123 includes via portions 123V formed in the openings 122P of the first dielectric layer 122 to be in physical and electrical contact with the corresponding second conductive pads 121. The respective via portion 123V may be tapered in a direction from the second side 101b toward the first side 101a. That is, the tapering direction of the via portion 123V is opposite to the tapering direction of the via portion 113V of the first conductive pattern 113. The first conductive pattern 123 may further include pad portions 123P connected to the via portions 123V and overlying the first dielectric layer 122. The first conductive pattern 123 may further include line portions (not shown) connected to the pad portions 123P and horizontally extending on the first dielectric layer 122.

With continued reference to FIG. 8, after forming the first conductive pattern 123, a second dielectric layer 124 having openings 124P may be formed on the first dielectric layer 122 to cover the first conductive pattern 123. For example, a portion of the first conductive pattern 123 is exposed by the openings 124P of the second dielectric layer 124. A second conductive pattern 125 may then be formed on the second dielectric layer 124 and fill the openings 124P of the second dielectric layer 124 to be in physical and electrical contact with the first conductive pattern 123. Next, a third dielectric layer 126 having openings 126P may be formed on the second dielectric layer 124 to cover the second conductive pattern 125. A third conductive pattern 127 may then be formed on the third dielectric layer 126 and fill the openings 126P of the third dielectric layer 126 to be in physical and electrical contact with the second conductive pattern 125, and then an outermost dielectric layer 128 having openings 128P may be formed on the third dielectric layer 126 to cover the third conductive pattern 127. An outermost conductive pattern 129 may then be formed on the outermost dielectric layer 128 and fill the openings 128P of the outermost dielectric layer 128 to be in physical and electrical contact with the third conductive pattern 127.

Still referring to FIG. 8, a surface finishing process is optionally performed on the pad portions 129P of the outermost conductive pattern 129 for the subsequently mounting process. For example, a surface finishing layer 1291 is conformally deposited on the outermost surface of the respective pad portions 129P of the outermost conductive pattern 129. The combination of the dielectric layers (e.g., 122, 124, 126, and 128), the conductive patterns (e.g., 123, 125, 127, and 129), and the second conductive pads 121 may be collectively viewed as the second redistribution structure 120. It is understood that the configuration of the second redistribution structure 120 shown herein is only for illustrative purpose, and the number of the dielectric layers and the number of the conductive patterns can be selected based on product and circuit requirements and are not limited in the disclosure.

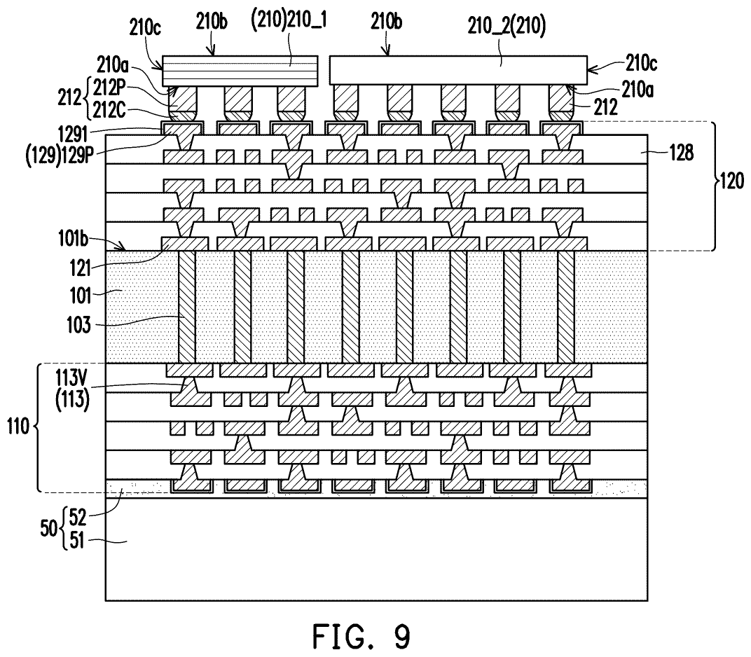

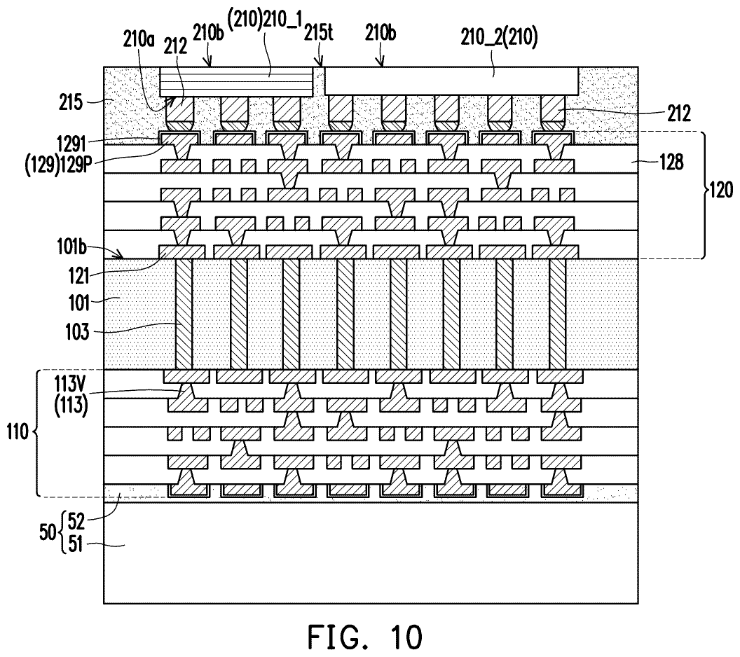

Referring to FIG. 9 and FIG. 8, one or more chip(s) 210 may be mounted on the second redistribution structure 120 through chip connectors 212. The chips 210 may perform a variety of electrical functions necessary for given applications. The chips 210 may be the same type of devices or may include different types of devices. For example, the chip 210_1 is a three-dimensional (3D) chip including multiple semiconductor substrates stacked upon one another. The chip 210_2 may also be a 3D chip or may be a different type of chips to perform a different function than the chip 210_1. In some embodiments, the respective chip 210 includes an active side 210a facing the second redistribution structure 120, a back side 210b opposite to the active side 210a, and a sidewall 210c connected to the active side 210a and the back side 210b. The chip connectors 212 are disposed at the active side 210a and may be or may include C4 bumps, micro-bumps, etc.

In some embodiments, the respective chip connector 212 includes a pillar portion 212P connected to the active side 210a and a cap portion 212C connecting the pillar portion 212P to the corresponding pad portion 129P of the second redistribution structure 120 (or the surface finishing layer 1291, if any). The pillar portion 212P and the cap portion 212C may be made of different materials. For example, the pillar portion 212P includes copper or the like, while the cap portion 212C includes solder material. A reflow process may be performed on the cap portions 212C such that the chip connectors 212 are physically and electrically coupled to the pad portions 129P of the second redistribution structure 120 (or the surface finishing layer 1291, if any). The second redistribution structure 120 may have the circuitry with fine pitches so as to meet the I/O pitch requirements of the chips 210.

Referring to FIG. 10 and FIG. 9, an insulating layer 215 may be formed on the outermost dielectric layer 128 of the second redistribution structure 120 to cover the chips 210 for protection. For example, the insulating layer 215 extends along the sidewalls 210c of the respective chip 210 and further extends into the gap between the active side 210a of the respective chip 210 and the pad portions 129P of the second redistribution structure 120 to surround the respective chip connector 212 and the respective pad portion 129P (or the surface finishing layer 1291, if any). The insulating layer 215 may be or may include molding compound, molding underfill, or the like, and may be formed by a molding process or other suitable process. Other types of insulating material may be used. A planarization process is optionally performed on the insulating layer 215 until the back side 210b of the chip(s) 210 is revealed. For example, the back side 210b of the chip(s) 210 is substantially coplanar with the top surface 215t of the insulating layer 215. Alternatively, the formation of the insulating layer 215 is omitted.

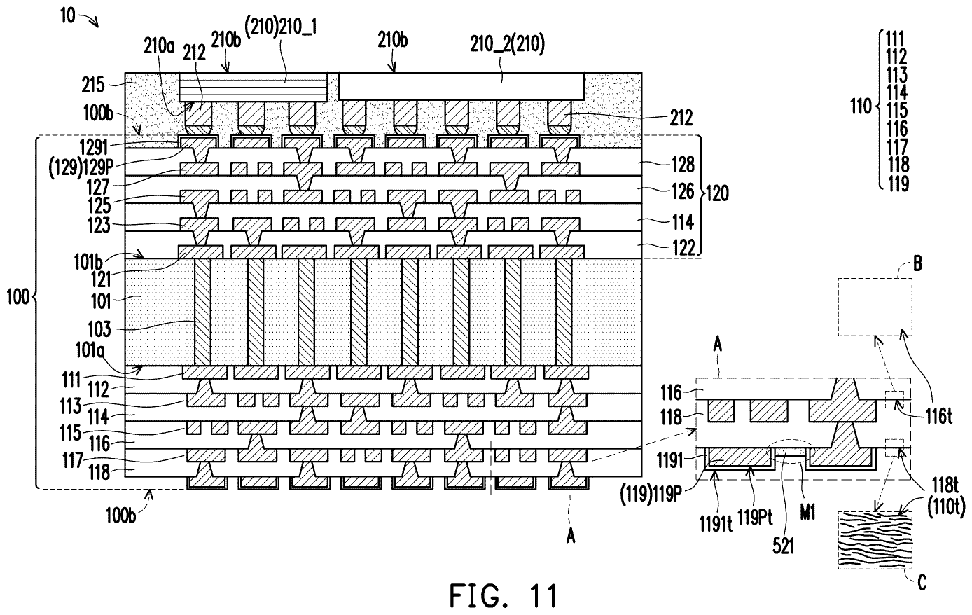

Referring to FIG. 11 and FIG. 10, the temporary protection structure 50 may be removed to expose the pad portions 119P of the outermost conductive pattern 119 (or the surface finishing layer 1191, if any) and the outermost dielectric layer 118 of the first redistribution structure 110. For example, the removing process of the temporary protection structure 50 includes applying the external energy (e.g., UV light, visible light, heat, etc.) to the temporary adhesive layer 52 to weaken (or decompose) the temporary adhesive layer 52, the temporary adhesive layer 52 may thus reduce or lose its adhesiveness. The temporary adhesive layer 52 along with the temporary carrier 51 may then be peeled off or de-bonded from the first redistribution structure 110. Other suitable techniques (etching or the like) may be used to release the temporary protection structure 50 from the first redistribution structure 110.

In some embodiments, after de-bonding the temporary adhesive layer 52 from the first redistribution structure 110, some residues 521 of the temporary adhesive layer 52 may be left in the fine seams M1 of the first redistribution structure 110, as shown in the enlarged view outlined in the dashed box A. The fine seams M1 may include the fine spacing between adjacent pad portions 119P, the seams at the interface of the outermost dielectric layer 118 and the outermost conductive pattern 119 (or the surface finishing layer 1191, if any), or the like.

A cleaning process (e.g., plasma treatment or the like) is optionally performed on the outermost surface 110t of the first redistribution structure 110 to remove the residues 521 left on the outermost surface 110t of the first redistribution structure 110. In some embodiments, a surface roughness of the outermost surface 118t of the outermost dielectric layer 118 is increased by the cleaning process (e.g., the surface treatment). For example, the surface roughness of the outermost surface 118t of the outermost dielectric layer 118 is greater than the surface roughness of the surface 116t of the third dielectric layer 116 facing (or connected to) the outermost dielectric layer 118. As shown in the top view of the dot-dashed box B, the surface 116t of the third dielectric layer 116 is relatively smooth and no ripples formed thereon. As shown in the dot-dashed box C, the ripples are formed on the outermost dielectric layer 118 to render the roughed surface (i.e. the outermost surface 118t) due to the plasma treatment, as seen in the top view. The portion of the outermost surface 118t including the ripples may be viewed as a roughed portion of the outermost dielectric layer 118. In some embodiments, some residues 521 of the temporary adhesive layer 52 may still be remained on the fine seams M1 of the first redistribution structure 110 after the cleaning process. In such cases, a portion of the outermost surface 118t of the outermost dielectric layer 118 may be protected by the residues 521 without being damaged. For example, the portion of the outermost surface 118t of the outermost dielectric layer 118 on which the residues 521 is left is smoother than another portion of the outermost surface 118t of the outermost dielectric layer 118 which has ripples formed thereon.

Still referring to FIG. 11, a semiconductor structure 10 is provided. For example, the semiconductor structure 10 includes a substrate 100 having a first side 100a and a second side 100b opposite to the first side 100a, the chip(s) 210 disposed on and electrically coupled to the second side 100b of the substrate 100, and the insulating layer 215 optionally formed on the second side 100b of the substrate 100 to cover the chip(s) 210. The substrate 100 may include the core layer 101, the through core vias 103 penetrating through the core layer 101 to provide the vertical and electrical connections between the first side 101a and the second side 101b of the core layer 101, the first redistribution structure 110 disposed on the first side 101a of the core layer 101 and electrically coupled to the through core vias 103, the second redistribution structure 120 disposed on the second side 101b of the core layer 101 and electrically coupling the chip(s) 210 to the first redistribution structure 110 through the through core vias 103.

In some embodiments, the first redistribution structure 110 and the second redistribution structure 120 are arranged symmetrically with respect to the core layer 101. For example, the number of the dielectric layers (e.g., 112, 114, 116, and 118) of the first redistribution structure 110 is equal to the dielectric layers (e.g., 122, 124, 126, and 128) of the first redistribution structure 120. In some embodiments, the conductive pads (e.g., 111 and 121) and the conductive patterns (e.g., 113, 115, 117, 119, 123, 125, 127, and 129) are arranged symmetrically on opposite sides (e.g., 101a and 101b) of the core layer 101. The through core vias 103 formed in the core layer 101 may be arranged in a dense manner such that the circuitries formed on the opposing sides (e.g., 101a and 101b) of the core layer 101 may be formed as fine-pitched redistribution layer (RDL) so as to satisfy the demands of the fine-pitched chip connectors 212. The substrate 100 of the semiconductor structure 10 may thus be viewed as a dual-side and high-density substrate. Such semiconductor structure 10 may be applicable for any high-density applications.

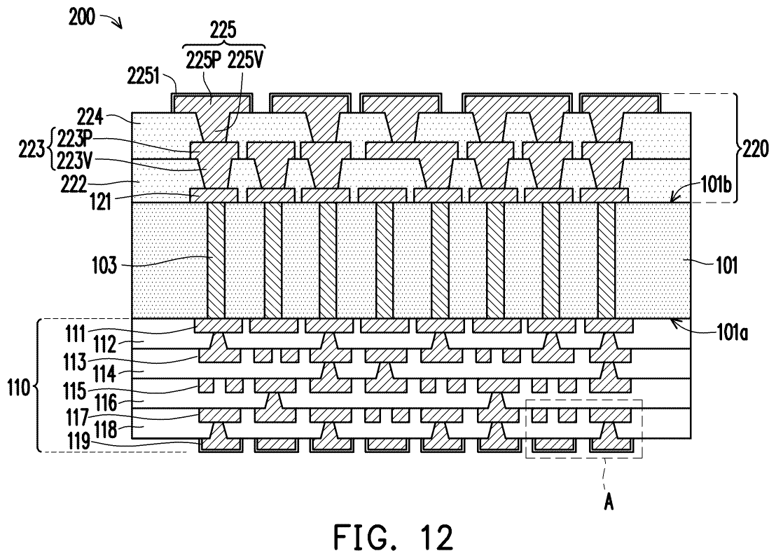

FIG. 12 is a schematic cross-sectional view illustrating a dual-side and high-density substrate according to some embodiments. The same reference numbers are used in FIGS. 11-12 and the description to refer to the same or like parts. Referring to FIG. 12 and FIG. 11, a substrate 200 shown in FIG. 12 is similar to the substrate 100 in FIG. 11, and thus the detailed descriptions are not repeated herein. The substrate 200 includes the core layer 101 including the first side 101a and the second side 101b opposite to the first side 101a, the through core vias 103 penetrating through the core layer 101 to provide the vertical and electrical connections between the first side 101a and the second side 101b, the first redistribution structure 110 disposed on the first side 101a of the core layer 101 and electrically coupled to the through core vias 103, the second redistribution structure 220 disposed on the second side 101b of the core layer 101 and electrically coupled to the first redistribution structure 110 through the through core vias 103.

With continued reference to FIG. 12, the second redistribution structure 220 may include second conductive pads 121, a first dielectric layer 222 overlying the second side 101b of the core layer 101 and exposing at least a portion of the respective second conductive pad 121, a first conductive pattern 223 including via portions 223V passing through the first dielectric layer 222 to land on the corresponding second conductive pads 121 and pad portions 223P overlying the first dielectric layer 222 and connected to the via portions 223V, an outermost dielectric layer 224 overlying the first dielectric layer 222 and exposing at least a portion of the respective pad portion 223P, and an outermost conductive pattern 225 including via portions 225V passing through the outermost dielectric layer 224 to land on the corresponding pad portions 223P and pad portions 225P overlying the outermost dielectric layer 224 and connected to the via portions 225V. In some embodiments, a surface finishing layer 2251 is conformally deposited on the outer surface of the respective pad portions 225P of the outermost conductive pattern 225. Alternatively, the surface finishing layer 2251 is omitted.

In some embodiments, one or more dielectric layers (e.g., 222 and 224) of the second redistribution structure 220 is/are made of a different material (e.g., ABF or the like) than the material of the dielectric layers (e.g., 112, 114, 116, and 118) of the first redistribution structure 110. The first redistribution structure 110 and the second redistribution structure 220 may be arranged in asymmetrical manner. For example, the number of the dielectric layers (e.g., 222 and 224) of the second redistribution structure 220 may be less than the number of the dielectric layers (e.g., 112, 114, 116, and 118) of the first redistribution structure 110. Alternatively, the number of the dielectric layers of the second redistribution structure 220 is greater than the number of the dielectric layers of the first redistribution structure 110. The conductive patterns (e.g., 113, 115, 117, 119, 223, and 225) may be arranged asymmetrically on opposite sides (e.g., 101a and 101b) of the core layer 101. For example, the size (e.g., the thickness, the width, the length, etc.) of the conductive patterns (e.g., 223, and 225) of the second redistribution structure 220 is greater than that of the conductive patterns (e.g., 113, 115, 117, and 119) of the first redistribution structure 110. In some embodiments, the line/spacing of the conductive patterns (e.g., 223, and 225) of the second redistribution structure 220 is greater than that of the conductive patterns (e.g., 113, 115, 117, and 119) of the first redistribution structure 110. For example, the second redistribution structure 220 is viewed as a coarse redistribution structure including a coarse circuitry, while the first redistribution structure 110 is viewed as a fine redistribution structure including a fine circuitry. By this configuration, the substrate 200 may enable a high-density integration for various high-density applications.

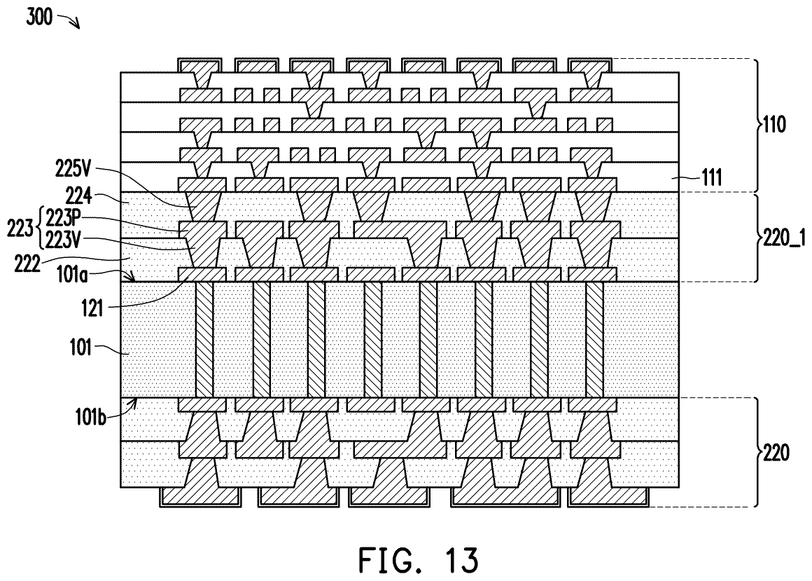

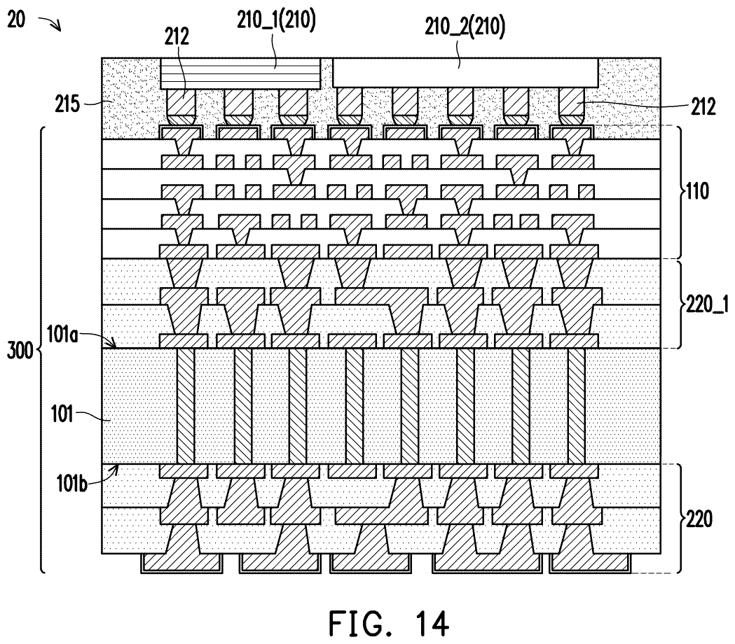

FIG. 13 is a schematic cross-sectional view illustrating a dual-side and high-density substrate according to some embodiments. The same reference numbers are used in FIGS. 5, 12 and 13 and the description to refer to the same or like parts. Referring to FIG. 13 and FIGS. 5 and 12, a substrate 300 shown in FIG. 13 is similar to the substrate 200 in FIG. 12, except that the substrate 300 further includes a third redistribution structure 220_1 disposed on the first side 101a and between the core layer 101 and the first redistribution structure 110. The third redistribution structure 220_1 may be similar to the second redistribution structure 220. For example, the third redistribution structure 220_1 is also a coarse redistribution structure. In some embodiments, circuitries in both of the second redistribution structure 220 and the third redistribution structure 220_1 are coarser than circuitries in the first redistribution structure 110.

With continued reference to FIG. 13, the via portions 223V of the first conductive pattern 223 may land on the second conductive pads 121, and the via portions 225V of the second conductive pattern 225 may connect the pad portions 223P of the first conductive pattern 223 to the first conductive pads 111 of the first redistribution structure 110. The first dielectric layer 222 of the third redistribution structure 220_1 may overlay the core layer 101 and the second dielectric layer 224 may be between the first dielectric layer 222 and the first redistribution structure 110.

FIG. 14 is a schematic cross-sectional view illustrating a semiconductor structure having a dual-side and high-density substrate according to some embodiments. The same reference numbers are used in FIGS. 13-14 and the description to refer to the same or like parts. Referring to FIG. 14 and also referring to FIG. 13 and FIG. 11, a semiconductor structure 20 including the substrate 300 and the chips 210 may be provided. The chips 210 may be electrically coupled to the first redistribution structure 110 through the chip connectors 212 and may be laterally covered by the insulating layer 215. The configuration of the chips 210 may be similar to the chips 210 described in FIG. 11, and thus the detailed descriptions are not repeated herein.

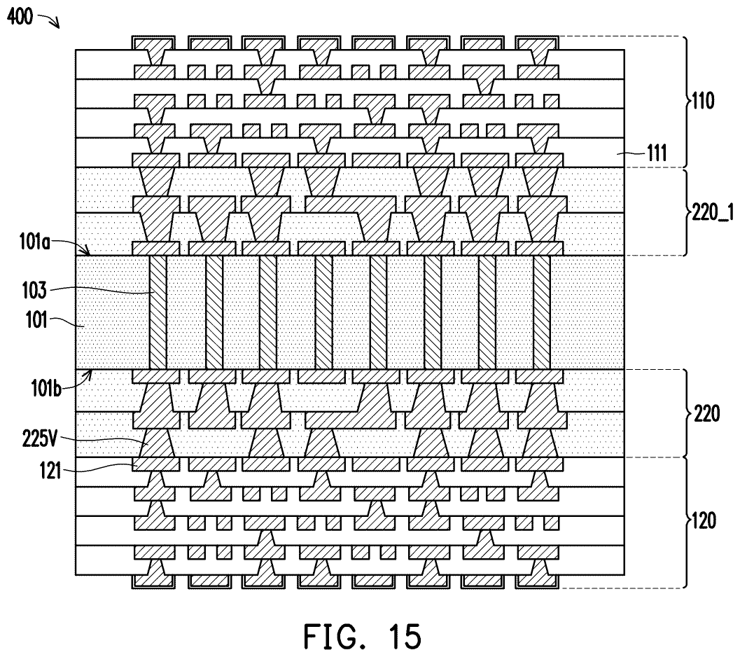

FIG. 15 is a schematic cross-sectional view illustrating a dual-side and high-density substrate according to some embodiments. The same reference numbers are used in FIGS. 11-12 and 15 and the description to refer to the same or like parts. Referring to FIG. 15 and FIG. 11-and 13, a substrate 400 shown in FIG. 15 is similar to the substrate 200 in FIG. 13, except that the substrate 400 further includes additional second redistribution structure 120 coupled to the second redistribution structure 220. The additional second redistribution structure 120 may be similar to the second redistribution structure 120 shown in FIG. 11. For example, the second conductive pads 121 of the additional second redistribution structure 120 land on the via portions 225V of the second redistribution structure 220. The additional second redistribution structure 120 may be referred to as a fine redistribution structure. In some embodiments, circuitries in the second redistribution structure 220 and the third redistribution structure 220_1 are coarser than circuitries in the additional second redistribution structure 120.

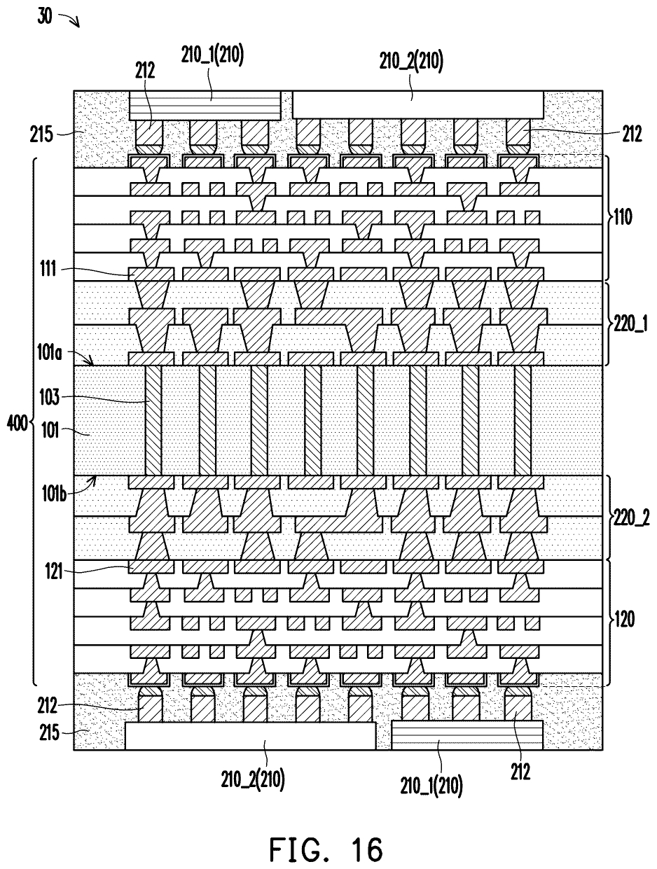

FIG. 16 is a schematic cross-sectional view illustrating a semiconductor structure having a dual-side and high-density substrate according to some embodiments. The same reference numbers are used in FIGS. 15-16 and the description to refer to the same or like parts. Referring to FIG. 16 and FIG. 15, a semiconductor structure 30 including the substrate 400 and the chips 210 may be provided. The first portion of the chips 210 may be electrically coupled to the first redistribution structure 110 and may be laterally covered by the insulating layer 215. The second portion of the chips 210 may be electrically coupled to the additional second redistribution structure 120 and may be laterally covered by the insulating layer 215. The configuration of the chips 210 may be similar to the chips 210 described in FIG. 11, and thus the detailed descriptions are not repeated herein.

Based on the above, the semiconductor structure includes the substrate including a dual-side fine circuitry manufactured by using one-side process. For example, after the formation (or partial formation) of the fine circuitry on one side of the core layer, the structure is protected and supported by the temporary protection structure (see FIG. 6). Then, the subsequent processes are performed on the other side of the core layer using the temporary protection structure as a support and protection. After the other fine circuitry (or the coarse circuitry as described in FIG. 12) is formed on the other side of the core layer, the temporary protection structure is removed, and thus the dual-side circuitry substrate is formed. The use of the temporary protection structure during the formation of the substrate may facilitate compensation of the warpage of the work-in process and reduction of the surface non-planarity of the work-in process (see FIGS. 6-7). In this manner, the overall flatness of the substrate may be improved, and the reliability and yield of the semiconductor structure may also be improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A semiconductor structure, comprising:
a substrate comprising:
a core layer comprising a first side and a second side opposite to the first side;
a through core via penetrating through the core layer;
a first redistribution structure disposed on the first side of the core layer, the first redistribution structure comprising an outermost dielectric layer, an outermost conductive pattern disposed in and on the outermost dielectric layer and electrically coupled to the through core via, an inner dielectric layer between the outermost dielectric layer and the core layer, wherein an outermost surface of the outermost dielectric layer comprises a portion rougher than a surface of the inner dielectric layer facing the outermost dielectric layer; and
a second redistribution structure disposed on the second side of the core layer and electrically coupled to the first redistribution structure through the through core via.

2. The semiconductor structure of claim 1, wherein a residue of a temporary adhesive layer is left on another portion of the outermost surface of the outermost dielectric layer.

3. The semiconductor structure of claim 2, wherein the residue of the temporary adhesive layer is at a spacing of pad portions of the outermost conductive pattern.

4. The semiconductor structure of claim 2, wherein the portion of the outermost surface of the outermost dielectric layer is caused a surface roughness greater than that of the another portion of the outermost surface of the outermost dielectric layer.

5. The semiconductor structure of claim 1, wherein the first redistribution structure and the second redistribution structure are arranged symmetrically with respect to the core layer.

6. The semiconductor structure of claim 1, further comprising:
a third redistribution structure disposed between the first redistribution structure and the core layer, wherein circuitries in both of the second and third redistribution structures are coarser than circuitries in the first redistribution structure.

7. The semiconductor structure of claim 6, further comprising:
a fourth redistribution structure coupled to the second redistribution structure, the second redistribution structure being between the core layer and the fourth redistribution structure, wherein the circuitries in the second redistribution structure are coarser than circuitries in the fourth redistribution structure.

8. The semiconductor structure of claim 1, wherein the core layer of the substrate is made of an inorganic material.

9. The semiconductor structure of claim 1, wherein the first redistribution structure further comprises a surface finishing layer conformally covering the outermost conductive pattern disposed on the outermost dielectric layer.

10. The semiconductor structure of claim 1, further comprising:
a chip disposed on and electrically coupled to the second redistribution structure of the substrate.

11. A manufacturing method of a semiconductor structure, comprising:
forming a through core via in a core layer, wherein the core layer comprises a first side and a second side opposite to the first side, and the through core via extends between the first and second sides;
forming a first redistribution structure on the first side of the core layer;
bonding a temporary protection structure to the first redistribution structure, wherein the temporary protection structure comprises a temporary carrier and a temporary adhesive layer bonding the temporary carrier to an outermost surface of the first redistribution structure, and a surface planarity of a surface the temporary adhesive layer connected to the temporary carrier is better than a surface planarity of the outermost surface of the first redistribution structure;
forming a second redistribution structure on the second side of the core layer using the temporary protection structure as a support; and
de-bonding the temporary protection structure from the first redistribution structure.

12. The manufacturing method of claim 11, wherein the outermost surface of the first redistribution structure comprises an outermost surface of an outermost conductive pattern and an outermost surface of an outermost dielectric layer.

13. The manufacturing method of claim 12, wherein after de-bonding the temporary protection structure from the first redistribution structure, a residue of the temporary adhesive layer is left on the outermost surface of the outermost dielectric layer and at a spacing of pad portions of the outermost conductive pattern.

14. The manufacturing method of claim 11, wherein de-bonding the temporary protection structure from the first redistribution structure comprises:
performing a cleaning process on the first redistribution structure, wherein after the cleaning process, the outermost surface of the first redistribution structure is formed on a portion of an outermost surface of an outermost dielectric layer, and a surface roughness of the portion of the outermost surface of the outermost dielectric layer is greater than that of a surface of a dielectric layer of the first redistribution structure facing the outermost dielectric layer.

15. The manufacturing method of claim 14, wherein after the cleaning process, a residue of the temporary adhesive is left on another portion of the outermost surface of the outermost dielectric layer, and the surface roughness of the portion of the outermost surface of the outermost dielectric layer is greater than that of the another portion of the outermost surface of the outermost dielectric layer.

16. The manufacturing method of claim 11, wherein a coefficient of thermal expansion of the temporary carrier is greater than that of the core layer.

17. The manufacturing method of claim 11, wherein a Young's modulus of the temporary carrier is a Young's modulus of a dielectric material in the first redistribution structure.

18. The manufacturing method of claim 11, wherein:
after forming the first redistribution structure, the first redistribution structure and the core layer are warped, and
bonding the temporary protection structure to the first redistribution structure comprises flattening a warpage of the first redistribution structure and the core layer using the temporary protection structure.

19. The manufacturing method of claim 11, further comprising:
coupling a chip on the second redistribution structure, wherein during the coupling, the temporary protection structure serves as the support.

20. The manufacturing method of claim 19, further comprising:
forming an insulating layer on the second redistribution structure to cover the chip, wherein when forming the insulating layer, the temporary protection structure serves as the support.
